(19) United States
(12) Patent Application Publication
(10) Pub. No.: US 2014/0184201 A1
(43) Pub. Date: Jul. 3, 2014

(54) POSITION DETECTOR

(71) Applicant: DENSO CORPORATION, Kariya-city (JP)

(72) Inventors: Naoaki Kouno, Chiryu-city (JP); Tetsuji Yamanaka, Obu-city (JP)

(73) Assignee: DENSO CORPORATION, Kariya-city (JP)

(21) Appl. No.: 14/142,195

(22) Filed: Dec. 27, 2013

(30) Foreign Application Priority Data
Dec. 27, 2012 (JP) 2012-286100

(51) Int. Cl. G01B 7/00; G01R 33/07

(52) U.S. Cl. CPC G01B 7/003; G01R 33/072
USPC 324/207.2

(57) ABSTRACT

A position detector provides a wide dynamic range for detecting a magnetic flux density. The position detector has a magnetic flux detector with a Hall IC disposed within a gap between first and second magnetic flux transmission parts that allow rotation of the Hall IC relative to a rotating body for outputting a signal reflecting a passing magnetic flux density. First and second magnetic flux collectors sandwich the Hall IC in a facing direction that matches a facing direction of the first and second magnetic flux transmission parts. The first and second magnetic flux collectors have an area size relationship such that spill magnetic flux flows to the Hall IC in a concentrated manner. Thus, the dynamic range detected by the magnetic flux density detector is widened and a position detection accuracy of the position detector is improved.

### CROSS-REFERENCE TO RELATED APPLICATION

The present application is based on and claims the benefit of priority of Japanese Patent Application No. 2012-286100 filed on Dec. 27, 2012, the disclosure of which is incorporated herein by reference.

### TECHNICAL FIELD

The present disclosure generally relates to a position detector for detecting a position of a detection object.

### BACKGROUND

Generally, a magnetic-type position detector detects a change in the position of a detection object relative to a reference part. The magnetic-type position detector may utilize a magnetic flux generator such as a magnet. For example, a position detector disclosed in a patent document 1 (i.e., Japanese Patent Laid-Open No. JP-A-H08-292004) is configured to form a closed magnetic circuit having two magnets and two magnetic flux transmission parts that are disposed on a reference part. In such structure, the two magnets are respectively bound by the ends of the two mutually-facing magnetic flux transmission parts. A flow of spill magnetic fluxes from one transmission part to the other occurs within a gap between the respective ends of the two magnetic flux transmission parts. A magnetic flux density detector is configured to move together with the detection object within the gap between the two magnetic flux transmission parts, and to output a detection signal according to the magnetic flux passing therethrough. In such manner, the position detector detects the position of the detection object relative to the reference part based on an output signal that is output from the magnetic flux detector.

The position detector of the patent document 1 has the magnetic flux density detector positioned between two yoke plates. Thereby, a spill magnetic flux in between two magnetic flux transmission parts is collected by the yoke plates, for an increase of the amount of magnetic flux which passes through the magnetic flux density detector. Generally, in a magnetic type position detector, if the dynamic range of the magnetic flux density which is detected by the magnetic flux density detector is narrow, the signal accuracy outputted from the magnetic flux density detector will decrease. The position detector in the patent document 1 may, in view of such knowledge, require a larger magnetic flux collecting yoke (i.e., the yoke plate) or a larger magnet which is capable of generating a larger amount of magnetic flux, for the increase of the amount of the magnetic flux detected by the detector. However, use of the larger yoke and/or magnet may lead to a position detector having a larger volume or an increase in manufacturing costs.

### SUMMARY

It is an object of the present disclosure to provide a position detector that has a magnetic flux density detector for detecting a magnetic flux density within a wide dynamic range.

In an aspect of the present disclosure, the position detector detects a position of a detection object that moves relative to a reference part. The position detector includes a first magnetic flux transmission part disposed on one of the detection object or the reference part, the first magnetic flux transmission part having a first end and a second end and a second magnetic flux transmission part facing the first magnetic flux transmission part in a facing direction and disposed to define a gap between the first magnetic flux transmission part and the second magnetic flux transmission part, the second magnetic flux transmission part having a first end and a second end. A first magnetic flux generator is disposed at a position between the first end of the first magnetic flux transmission part and the first end of the second magnetic flux transmission part. A second magnetic flux generator is disposed at a position between the second end of the first magnetic flux transmission part and the second end of the second magnetic flux transmission part. A magnetic flux density detector (i) is disposed on an other of the detection object or the reference part to be movable within the gap relative to the one of the detection object or the reference part and (ii) having a signal output element that outputs a signal according to a density of a magnetic flux passing therethrough. A magnetic flux collector has two facing parts contacting opposite sides of the magnetic flux density detector with each of the two facing parts having a first side that faces the magnetic flux density detector and a second side that is a side opposite to the first side. The two facing parts are aligned in a direction that matches the facing direction of the first magnetic flux transmission part and the second magnetic flux transmission part. When the first side has an area size defined as A1 and the second side has an has an area size defined as A2, the magnetic flux collector is configured to fulfill an area size relationship of A1<A2.

Further, the signal output element has faces adjacent to each of the two facing parts of the magnetic flux collector, and at least one of the faces adjacent to each of the two facing parts has an area size defined as A0. As such, the signal output element and the magnetic flux collector are configured to fulfill a relationship of A0≦A1.

Moreover, the detection object rotates relative to the reference part and the first magnetic flux transmission part and the second magnetic flux transmission part have a curved shape that is concentric to a center of rotation of the detection object.

Furthermore, the detection object moves linearly relative to the reference part, and the first magnetic flux transmission part and the second magnetic flux transmission part have a straight shape extends along a path of relative movement of the detection object.

In other words, the position detector detects a relative move position of a detection object, which is a position after a relative move of the detection object relative to a reference part, the detector includes: a first magnetic flux transmission part, a second magnetic flux transmission part, a first magnetic flux generator, a second magnetic flux generator, a magnetic flux density detector and a magnetic flux collector.

The first magnetic flux transmission part is disposed on one of the detection object and the reference part. The second magnetic flux transmission part is disposed on one of the detection object or the reference part, so that a gap is formed at a position between the first and second magnetic flux transmission parts.

The first magnetic flux generator is disposed at a position between a first end of the first magnetic flux transmission part and a first end of the second magnetic flux transmission part. Thereby, the magnetic flux generated by the first magnetic flux generator is transmitted from the first end of the first and second magnetic flux transmission parts to a second end of first and second magnetic flux transmission parts.

The second magnetic flux generator is disposed at a position between the second end of the first magnetic flux transmission part and the second end of the second magnetic flux transmission part. Thereby, the magnetic flux generated by the second magnetic flux generator is transmitted from the second end of the first and second magnetic flux transmission parts to the first end of first and second magnetic flux transmission parts.

The magnetic flux density detector is disposed on the one of the detection object or the reference part so that the detector is movable relative to the other of the detection object or the reference part in the gap between the first and second magnetic flux transmission parts. The magnetic flux density detector outputs a signal according to a density of the magnetic flux passing through the detector. In such a structure, the magnetic flux passing through the magnetic flux density detector is, mainly, a spill magnetic flux, which flows through the gap between the first and second magnetic flux transmission parts from one of the two transmission parts to the other (i.e., the magnetic flux flowing either from the first part to the second part or from the second part to the first part).

By devising the above-mentioned configuration, the position detector is enabled to detect a position of the detection object relative to the reference part based on the signal outputted by the magnetic flux density detector.

A magnetic flux collector, provided in two facing parts, sandwiches or binds the magnetic flux density detector in between the two facing parts, and the two pieces of collector face each other in the same manner as the two magnetic flux transmission parts that face each other. In other words, the facing direction of the two collectors is the same direction as the facing direction of the two transmission parts. In such configuration, the spill magnetic flux which flows through the gap between the first magnetic flux transmission part and the second magnetic flux transmission part is concentrated and collected to flow to the magnetic flux density detector (i.e., to pass therethrough). Therefore, a dynamic range of the magnetic flux density detected by the magnetic flux density detector is widened, and a position detection accuracy of the position detector is improved.

In the present disclosure, when an area size of a density detector side face of the magnetic flux collector is designated as A1 and an area size of an opposite side face of the magnetic flux collector is designated as A2, a relationship between A1 and A2 in the magnetic flux collector is configured as A1<A2. Thereby, the spill magnetic flux which flows through the gap between the first magnetic flux transmission part and the second magnetic flux transmission part is controlled to flow to (i.e., to pass through) the magnetic flux density detector in a further concentrated manner. Therefore, a dynamic range of the magnetic flux density detected by the magnetic flux density detector is widened and a position detection accuracy of the position detector is improved.

### BRIEF DESCRIPTION OF THE DRAWINGS

Other objects, features and advantages of the present disclosure become more apparent from the following detailed description made with reference to the accompanying drawings, in which:

FIG. 1 is a sectional view of a position detector and an actuator in a first embodiment of the present disclosure;

FIG. 2 is a II-II line sectional view of FIG. 1;

FIGS. 3A, 3B, and 3C are views of a magnetic flux collector seen from a side, a bottom and a top in the first embodiment of the present disclosure;

FIG. 4 is a diagram of a relationship between (i) a detected magnetic flux density detected by the detector in the first embodiment of the present disclosure and by a magnetic flux density detector in a comparative example and (ii) a position of a detection object relative to a reference part;

FIG. 5 is a sectional view of the position detector in the comparative example;

FIGS. 6A, 6B, and 6C are of a magnetic flux collector seen from a side, a bottom and a top views in a second embodiment of the present disclosure;

FIGS. 7A, 7B, and 7C are views of a magnetic flux collector seen from a side, a bottom and a top in a third embodiment of the present disclosure;

FIGS. 8A, 8B, and 8C are views of a magnetic flux collector seen from a side, a bottom and a top in a fourth embodiment of the present disclosure;

FIGS. 9A, 9B, and 9C are views of a magnetic flux collector seen from a side, a bottom and a top in a fifth embodiment of the present disclosure; and

FIG. 10 is a sectional view of the position detector in a sixth embodiment of the present disclosure.

### DETAILED DESCRIPTION

Hereafter, the position detector in plural embodiments of the present disclosure and the actuator using the same are explained based on the drawing. In the plural embodiments, the same numerals are assigned to the same components, and explanation of the same components will not be repeated.

### First Embodiment

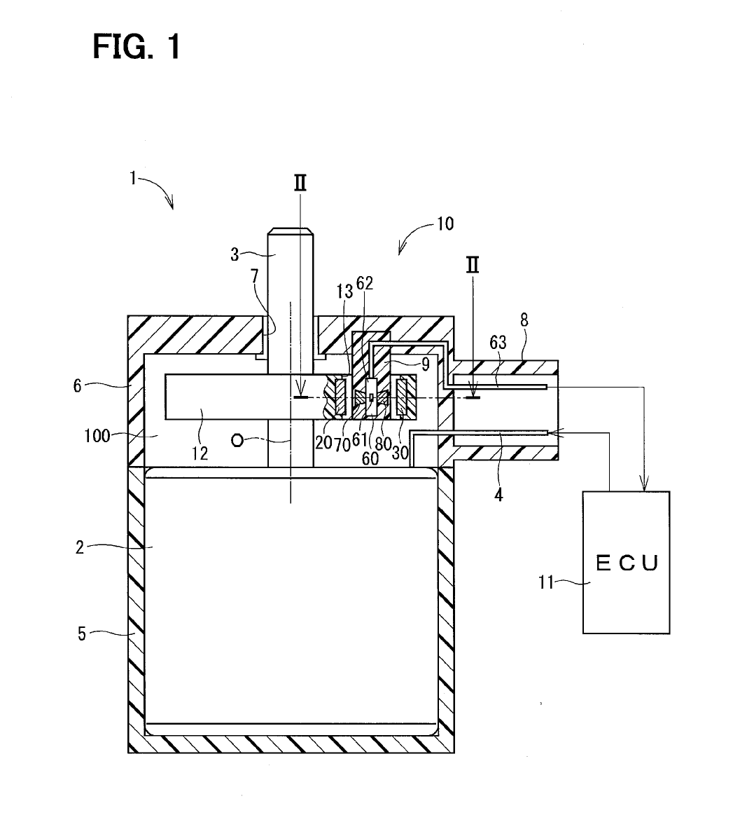

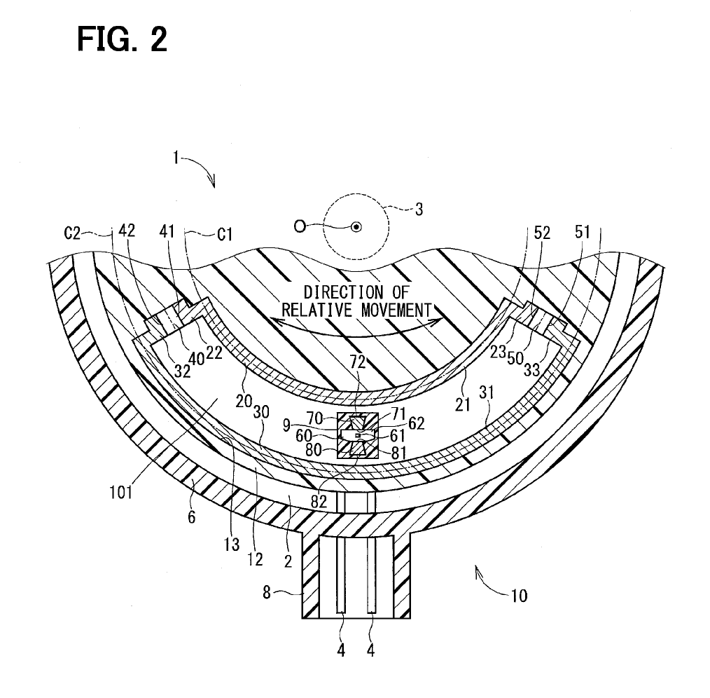

The position detector in the first embodiment of the present disclosure and the actuator using the same are shown in FIGS. 1 and 2.

An actuator 1 is used as a driving power source which drives a throttle valve of a vehicle (not illustrated), for example. The actuator 1 is provided with a motor 2, a housing 5, a cover 6, an electronic control unit (hereinafter “ECU”) 11, a rotating body 12, a position detector 10, together with other parts.

As shown in FIG. 1, the motor 2 has an output shaft 3, a motor terminal 4 and the like. An electric power is supplied to the motor 2 via the motor terminal 4. The motor 2 rotates by receiving the electric power from the terminal 4. Rotation of the motor 2 is outputted from the output shaft 3. The output shaft 3 is connected to a throttle valve via a geartrain (not illustrated) or the like, for example. Therefore, when the motor 2 rotates, the throttle valve also rotates.

The housing 5 is made of resin to have a cylinder shape with a bottom, for example, and has the motor 2 accommodated in an inside thereof.

The cover 6 is made of resin to have a cylinder shape with a bottom, for example, and has its opening abutted to an opening of the housing 5 in a state that the output shaft 3 inserted into a cavity 7 which is bored on the bottom of the cover 6. In such manner, a hollow space 100 is defined at a position between the cover 6 and the motor 2.

The cover 6 has a connector 8 formed in a pipe shape and extending in a radial outside direction from a cylinder shape body of the cover 6. In the connector 8, an end of the motor terminal 4 is exposed. The connector 8 is connected to an end of a wire harness leading to the ECU 11. Thereby, the electric power from the battery (not illustrated) is supplied to the motor 2 via the ECU 11, the wire harness, and the motor terminal 4.

The ECU 11 is a computer provided with a CPU serving as a calculation unit together with ROM, RAM serving as a memory unit, an input/output interface and other parts. The ECU 11 controls the operation of the various devices installed in the vehicle based on the signal from various sensors attached to various parts of the vehicle.

The ECU 11 controls the electric power supplied to the motor 2, for example, based on an accelerator opening signal from an accelerator pedal, or the like. When the electric power is supplied to the motor 2, the motor 2 rotates to rotate a throttle valve. Therefore, the throttle valve opens and closes an air intake passage, and an amount of an intake air flowing through the air intake passage is adjusted. In the present embodiment, the ECU 11 may also control a supply of the electric power to the motor 2 by an idle speed control (ISC) function, for example, irrespective of the opening signal from the accelerator pedal.

The rotating body 12 is, for example, made of resin to have a disc shape, and is disposed in the hollow space 100. The rotating body 12 is fixed onto the output shaft 3 with the output shaft 3 extending therethrough at its center. Therefore, when the output shaft 3 rotates, the rotating body 12 rotates together with the output shaft 3. Since the output shaft 3 and the throttle valve are connected by the geartrain, the rotation position of the rotating body 12 corresponds to the rotation position of the throttle valve.

According to the present embodiment, the position detector 10 detects the rotation position of the rotating body 12 that moves and rotates relative to the cover 6. Therefore, by detecting the rotation position of the rotating body 12 which rotates relative to the cover 6, the rotation position of the throttle valve is detected and an opening degree of the throttle valve is also detected. Thus, the position detector 10 is capable of serving as a throttle position sensor.

As shown in FIG. 1 and FIG. 2, the position detector 10 includes a first magnetic flux transmission part 20, a second magnetic flux transmission part 30, a magnet 40 serving as a first magnetic flux generator, a magnet 50 serving as a second magnetic flux generator, a Hall IC 60 serving as a magnetic flux density detector, a first magnetic flux collector 70, a second magnetic flux collector 80 and the like.

The first magnetic flux transmission part 20 is made of a material which has a relatively high magnetic permeability, such as a silicon steel, or the like. The first magnetic flux transmission part 20 is disposed in an arc-shape cavity 13 that is formed on the rotating body 12.

The first magnetic flux transmission part 20 has a center section 21, a first end 22, and a second end 23. The center section 21 has a shape which extends along a first virtual circle C1 that centers on a rotation axis O of the rotating body 12 (refer to FIG. 2). The first end 22 is formed to extend from one end of the center section 21 toward a radial outside of the first virtual circle C1. The second end 23 is formed to extend from the other end of the center section 21 toward the radial outside of the first virtual circle C1.

The second magnetic flux transmission part 30 is made of the material which has a relatively high magnetic permeability, such as a silicon steel or the like, similar to the first magnetic flux transmission part 20. The second magnetic flux transmission part 30 is disposed in the cavity 13 that is formed on the rotating body 12.

The second magnetic flux transmission part 30 has a center section 31, a first end 32, and an second end 33. The center section 31 has a shape which extends along a second virtual circle C2 that has a larger radius than the first virtual circle C1 and centers on the rotation axis O of the rotating body 12 (refer to FIG. 2). The first end 32 is formed to extend from one end of the center section 31 toward a radial inside of the second virtual circle C2. The second end 33 is formed to extend from the other end of the center section 31 to the radial inside of the second virtual circle C2.

As shown in FIGS. 1 and 2, the first magnetic flux transmission part 20 and the second magnetic flux transmission part 30 are disposed in the cavity 13 of the rotating body 12 so that the center section 21 of the first magnetic flux transmission part 20 and the center section 31 of the second magnetic flux transmission part 30 face each other in the radial direction of the first virtual circle C1. Thereby, an arc-shape gap 101 is formed between the center section 21 of the first magnetic flux transmission part 20 and the center section 31 of the second magnetic flux transmission part 30 (refer to FIG. 2).

The magnet 40 is a permanent magnet, such as a neodymium magnet, a ferrite magnet, or the like, for example. The magnet 40 has a magnetic pole 41 on one end, and has a magnetic pole 42 on the other end. The magnet 40 is magnetized so that a magnetic pole 41 side serves as an N pole, and a magnetic pole 42 side serves as an S pole. The magnet 40 is disposed at a position between the first end 22 of the first magnetic flux transmission part 20 and the first end 32 of the second magnetic flux transmission part 30 so that the magnetic pole 41 abuts the first end 22 of the first magnetic flux transmission part 20, and the magnetic pole 42 abuts the first end 32 of the second magnetic flux transmission part 30. Thereby, the magnetic flux generated by the magnetic pole 41 of the magnet 40 is transmitted from the first end 22 of the first magnetic flux transmission part 20 to the second end 23 via the center section 21.

The magnet 50 is also a permanent magnet, such as a neodymium magnet a ferrite magnet, or the like, for example, similar to the magnet 40. The magnet 50 has a magnetic pole 51 on one end, and has a magnetic pole 52 on the other end. The magnet 50 is magnetized so that a magnetic pole 51 side serves as an N pole, and a magnetic pole 52 side serves as an S pole. The magnet 50 is disposed at a position between the second end 33 of the second magnetic flux transmission part 30 and the second end 23 of the first magnetic flux transmission part 20 so that the magnetic pole 51 abuts the second end 33 of the second magnetic flux transmission part 30, and the magnetic pole 52 abuts the second end 23 of the first magnetic flux transmission part 20. Thereby, the magnetic flux generated by the magnetic pole 51 of the magnet 50 is transmitted from the second end 33 of the second magnetic flux transmission part 30 to the first end 32 via the center section 31.

Here, the spill magnetic flux flows through the gap 101, either from the first magnetic flux transmission part 20 to the second magnetic flux transmission part 30, or from the second magnetic flux transmission part 30 to the first magnetic flux transmission part 20.

In the present embodiment, the magnet 40 and the magnet 50 are configured to be the same permanent magnet having the same magnet volume, the same magnet type, the same magnet material composition, and the same magnetization adjustment method. Therefore, the flow of the spill magnetic flux flows from the second magnetic flux transmission part 30 to the first magnetic flux transmission part 20 in an area between a longitudinal center position of the gap 101 and the magnet 50, and the flow of the same flux flows from the first magnetic flux transmission part 20 to the second magnetic flux transmission part 30 in an area between the longitudinal center position and the magnet 40. More specifically, the closer the position along the longitudinal direction of the gap 101 is to the magnet 40 or to the magnet 50, the greater an absolute value of the magnetic flux density becomes. Further, the magnetic flux density is equal to 0 at the longitudinal center position of the gap 101.

Further, the magnetic flux at positions around the magnet 40 “flies” from the magnetic pole 41 to the magnetic pole 42, and the magnetic flux at positions around the magnet 50 “flies” from the magnetic pole 51 to the magnetic pole 52.

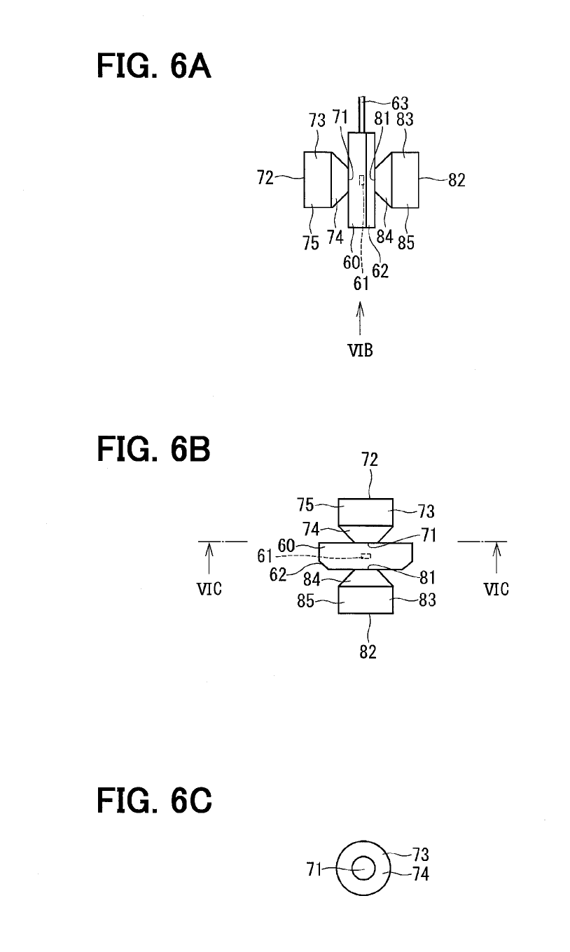

As shown in FIG. 2 and FIGS. 6A-6C, the Hall IC 60 has a Hall element 61 serving as a signal output element, as well as a sealer 62 and a sensor terminal 63. The Hall element 61 outputs a signal according to the density of the magnetic flux passing therethrough. The sealer 62 is made of resin and has a rectangular board shape, for example. A first end of the sensor terminal 63 is connected to the Hall element 61. The sealer 62 covers an entire Hall element 61, as well as the first end of the sensor terminal 63. In this case, the Hall element 61 is located at the center of the sealer 62.

The sealer 62 that seals the Hall IC 60 and the first end of the sensor terminal 63 are molded by a mold 9. The mold 9 is a resin mold, for example, and has a square pole shape. The sealer 62 that seals the Hall IC 60 is molded at a position on one end side of the mold 9.

The mold 9 is disposed on the cover 6 so that one end of the mold 9 is positioned in the gap 101 and the other end of the mold 9 is connected to the bottom of the cover 6. In such manner, the Hall IC 60 is rotatably moved, relative to the rotating body 12, in the gap 101 between the first magnetic flux transmission part 20 and the second magnetic flux transmission part 30. The cover 6 and the mold 9 are respectively equivalent to a reference part in the claims, and the rotating body 12 is equivalent to a detection object in the claims.

The sensor terminal 63 of the Hall IC 60 has a second end formed to be exposed in an inside of the connector 8 of the cover 6 by an insert-molding method in the cover 6. Therefore, when an end of the wire harness leading to the ECU 11 is connected to the connector 8, the Hall element 61 of the Hall IC 60 is connected to the ECU 11. Thereby, a signal from the Hall element 61 is transmitted to the ECU 11.

In this case, the magnetic flux passing through the Hall element 61 of the Hall IC 60 is mainly made of the spill magnetic flux which flows through the gap 101 between the first magnetic flux transmission part 20 and the second magnetic flux transmission part 30 either (i) from the second magnetic flux transmission part 30 to the first magnetic flux transmission part 20 or (ii) from the first magnetic flux transmission part 20 to the second magnetic flux transmission part 30.

In the present embodiment, the spill magnetic flux flows from the first magnetic flux transmission part 20 to the second magnetic flux transmission part 30 in an area between the longitudinal center position of the gap 101 and the magnet 40 as mentioned above. The spill magnetic flux flows from the second magnetic flux transmission part 30 to the first magnetic flux transmission part 20 in an area between the longitudinal center position of the gap 101 and the magnet 50. Further, when a position along the longitudinal direction of the gap 101 is closer to the magnet 40 or to the magnet 50, the greater an absolute value of the magnetic flux density becomes.

Therefore, if assumed that a flow direction of the spill magnetic flux flowing from the second magnetic flux transmission part 30 to the first magnetic flux transmission part 20 is a negative direction, when a position of the Hall IC 60 rotatably moves from a proximity of the magnet 50 to a proximity of the magnet 40 in the gap 101, the magnetic flux density monotonically increases from a negative value to a positive value, thereby (i) identifying a rotation position of the Hall IC 60 uniquely according to the detected magnetic flux density and thus (ii) outputting a signal that uniquely identifies the rotation position of the Hall IC 60.

According to the above-mentioned configuration, the ECU 11 is capable of detecting the rotation position of the rotating body 12 relative to the cover 6 based on the signal outputted from the Hall IC 60. In such manner, the rotation position and an opening degree of the throttle valve are detected.

The first magnetic flux collector 70 is made of a relatively high magnetically permeable material such as a permalloy or the like, and has a hexahedron body. The first magnetic flux collector 70 is disposed on a first side of the mold 9 so that a predetermined face 71 of the collector 70 faces or abuts a center of one face on a first magnetic flux transmission part 20 side of the sealer 62 of the Hall IC 60. An opposite face 72 of the first magnetic flux collector 70, which is opposite to the face 71, faces the center section 21 of the first magnetic flux transmission part 20.

The second magnetic flux collector 80 is, similar to the first magnetic flux collector 70, made of a relatively high magnetically permeable material such as a permalloy or the like, and has a hexahedron body. The second magnetic flux collector 80 is disposed on a second side of the mold 9 so that a predetermined face 81 of the collector 80 faces or abuts a center of one face on a second magnetic flux transmission part 30 side of the sealer 62 of the Hall IC 60. A face 82 of the second magnetic flux collector 80, which is opposite to the face 81, faces the center section 31 of the second magnetic flux transmission part 30.

Thus, the Hall IC 60 is sandwiched or bound in between the first magnetic flux collector 70 and the second magnetic flux collector 80, and such sandwiching or binding direction is substantially the same as the facing direction between the first magnetic flux transmission part 20 and the second magnetic flux transmission part 30. The spill magnetic flux which flows through the gap 101 between the first magnetic flux transmission part 20 and the second magnetic flux transmission part 30 is thus concentrated in such manner, and is directed to flow to (i.e., pass through) the Hall IC 60. The first magnetic flux collector 70 and the second magnetic flux collector 80 are respectively equivalent to a magnetic flux collector having two facing parts in the claims.

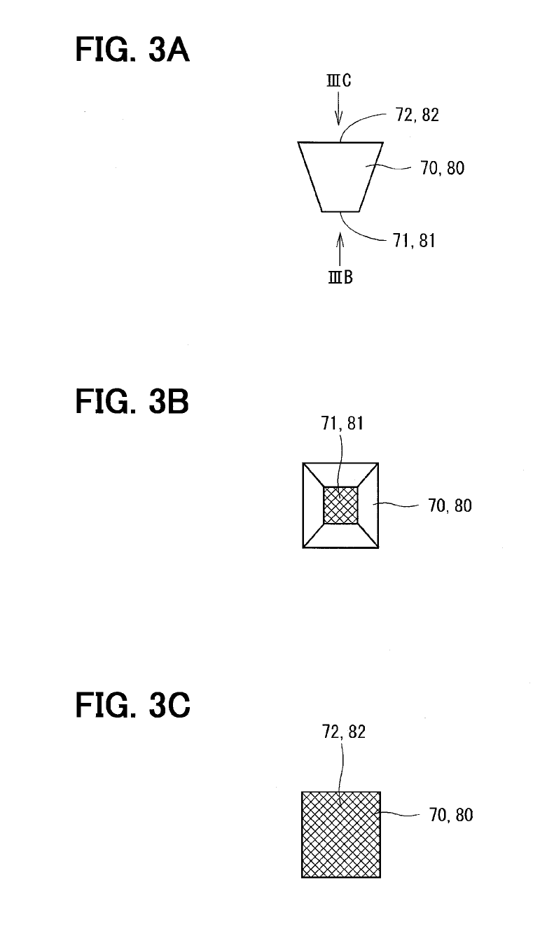

In the present embodiment, as shown in FIGS. 3A-3C, when (i) an area size of the face 71 on an IC 60 side of the first magnetic flux collector 70 and an area size of the face 81 on an IC 60 side of the second magnetic flux collector 80 are respectively designated as A1 (i.e., a hatching area in FIG. 3B) and (ii) an area size of the opposite face 72 on the opposite side of the first magnetic flux collector 70 that is not facing the IC 60 and an area size of the opposite face 82 on the opposite side of the second magnetic flux collector 80 are respectively designated as A2 (i.e., a hatching area in FIG. 3C), the first magnetic flux collector 70 and the second magnetic flux collector 80 are respectively formed to fulfill a relationship A1<A2.

Further, in the present embodiment, when an area size of a face on a first magnetic flux collector 70 side of the Hall element 61 or an area size of a face on a second magnetic flux collector 80 side of the Hall element 61 is designated as A0, the Hall element 61, the first magnetic flux collector 70 and the second magnetic flux collector 80 are respectively formed to fulfill a relationship A0<A1.

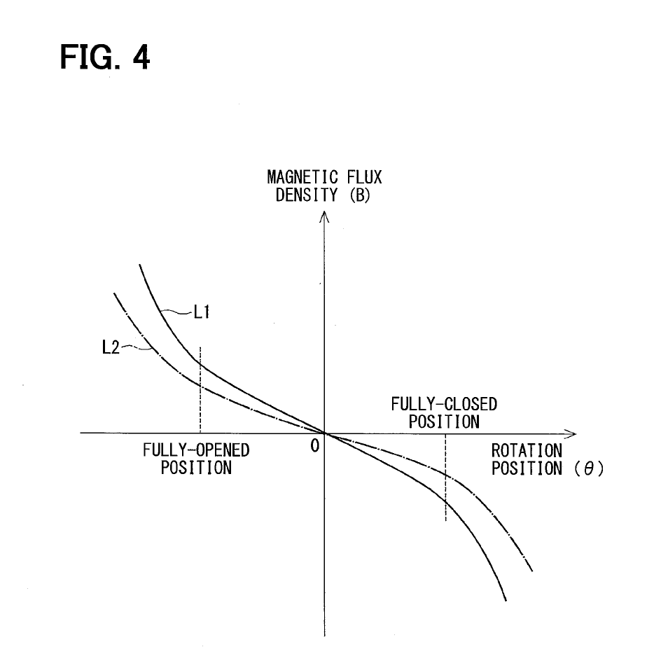

According to the present embodiment, the magnetic flux density detected by the Hall IC 60 is illustrated by a line L1 in FIG. 4. In addition to the spill magnetic flux, which flows between the first magnetic flux transmission part 20 and the second magnetic flux transmission part 30, the magnetic flux, which “flies” from the magnetic pole 41 to the magnetic pole 42 of the magnet 40, and the magnetic flux, which “flies” from the magnetic pole 51 to the magnetic pole 52 of the magnet 50, flows at or around the magnets 40 and 50 in the gap 101. Therefore, a change rate of the absolute value illustrated by the line L1 increases toward an end of the line L1.

In the present embodiment, the relationship between the magnetic flux density and the movable range (i.e., a range between the fully-closed position and the fully-opened position of the throttle valve) of the rotating body 12 is shown in FIG. 4. Thus, in the present embodiment, the position of the rotating body 12 is detected in a range in which the linearity of the line L1 is relatively high.

The advantages of the position detector in the present embodiment are clarified by describing a comparative example of a position detector in the following.

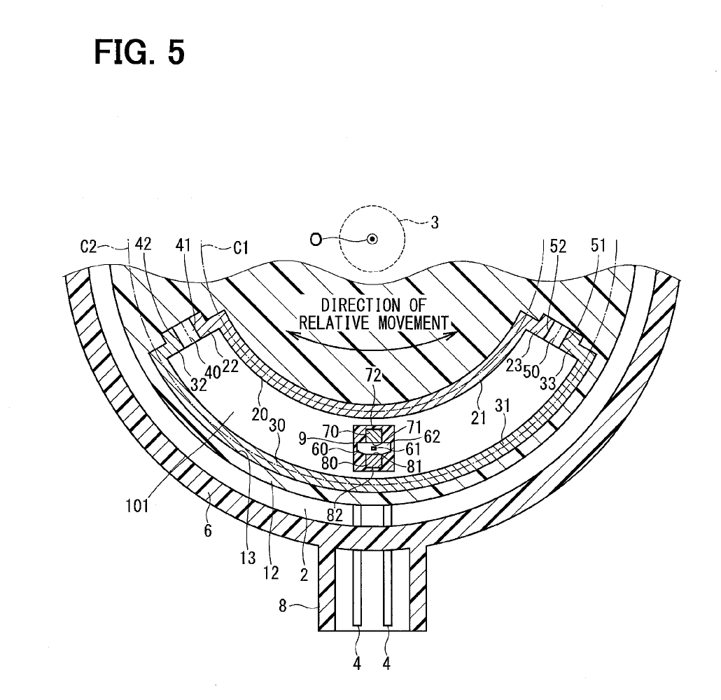

As shown in FIG. 5, in the comparative example, the first magnetic flux collector 70 and the second magnetic flux collector 80 are respectively formed to fulfill a relationship A1=A2. In such case, the face 72 and the face 82 in the present embodiment and the faces 71, 72, 81, 82 have the same area size.

In the comparative example, the magnetic flux density detected by Hall IC 60 is illustrated by a line L2 in FIG. 4, which is a dashed-dotted line. As readily understood from the comparison, the dynamic range of the magnetic flux density detected by the Hall IC 60 is wider in the present embodiment than in the comparative example. This is because improved (i.e., higher) magnetic flux collecting effects are achieved by the first and second magnetic flux collector 70, 80 based on the relationship A1<A2.

As explained above, in the present embodiment, the Hall IC 60 is sandwiched or bound in between the first magnetic flux collector 70 and the second magnetic flux collector 80, and such sandwiching or binding direction is substantially the same as the facing direction between the first magnetic flux transmission part 20 and the second magnetic flux transmission part 30. The spill magnetic flux which flows through the gap 101 between the first magnetic flux transmission part 20 and the second magnetic flux transmission part 30 is thus concentrated in such manner, and is directed to flow to (i.e., pass through) the Hall IC 60. Therefore, the dynamic range of the magnetic flux density detected by the Hall IC 60 is widened. Thus, the position detection accuracy of the position detector 10 is improved.

Further, in the present embodiment, when (i) the area size of the face 71 on an IC 60 side of the first magnetic flux collector 70 and the area size of the face 81 on an IC 60 side of the second magnetic flux collector 80 are respectively designated as A1, and (ii) the area size of the opposite face 72 on the opposite side of the first magnetic flux collector 70 not facing the IC 60 and the area size of the opposite face 82 on the opposite side of the second magnetic flux collector 80 are respectively designated as A2, the first magnetic flux collector 70 and the second magnetic flux collector 80 are respectively formed to fulfill a relationship A1<A2. In such manner, the spill magnetic flux which flows through the gap 101 between the first magnetic flux transmission part 20 and the second magnetic flux transmission part 30 is further concentrated and is directed to flow to (i.e., pass through) the Hall IC 60. Therefore, the dynamic range of the magnetic flux density detected by the Hall IC 60 is widened. Thus, the position detection accuracy of the position detector 10 is further improved.

In the present embodiment, when the area size of a face on a first magnetic flux collector 70 side of the Hall element 61 or the area size of a face on a second magnetic flux collector 80 side of the Hall element 61 is designated as A0, the first magnetic flux collector 70 and the second magnetic flux collector 80 are respectively formed to fulfill a relationship A0<A1. Therefore, for example, even when a misalignment in a surface direction is caused by a manufacturing process, or the like, between (i) the first magnetic flux collector 70 and/or the second magnetic flux collector 80 and (ii) the Hall element 61, the Hall element 61 can be easily positioned within an area between the face 71 of the first magnetic flux collector 70 and the face 81 of the second magnetic flux collector 80. Thereby, the reduction of the magnetic flux collecting effect by the collectors 70, 80 due to the misalignment between the collectors 70, 80 and the IC 61 is prevented.

### Second Embodiment

A part of the position detector in the second embodiment of the present disclosure is shown in FIGS. 6A-6C. The position detector in the second embodiment differs from the first embodiment in the shape of the first and second magnetic flux collector.

FIGS. 6A-6C shows the Hall IC, the first magnetic flux collector, and the second magnetic flux collector of the position detector in the second embodiment. According to the second embodiment, a first magnetic flux collector 73 has a cone part 74 and a cylinder part 75. The cone part 74 has a shape which may be a “pedestal” with a top part of a cone cut out by a plane that is in parallel with the bottom thereof. The cylinder part 75 is formed to have a single body with the cone part 74 with a first axial end that is connected to the bottom of the cone part 74.

According to the present embodiment, the face 71 of the first magnetic flux collector 73 (i.e., which is opposite to the bottom of the cone part 74, abuts a face of the sealer 62 at its center (i.e., the face on the first magnetic flux transmission part 20 side of the sealer 62 that seals the Hall IC 60). Thereby, the face 72 on a second axial end of the cylinder part 75 faces the center section 21 of the first magnetic flux transmission part 20.

A second magnetic flux collector 83 has a cone part 84 and a cylinder part 85. The cone part 84 has a shape which may be a “pedestal” with a top part of a cone cut out by a plane that is in parallel with the bottom thereof. The cylinder part 85 is formed to have a single body with the cone part 84 with a first axial end that is connected to the bottom of the cone part 84.

According to the present embodiment, the face 81 of the second magnetic flux collector 83 (i.e., which is opposite to the bottom of the cone part 84), abuts a face of the sealer 62 at its center (i.e., the face on the first magnetic flux transmission part 20 side of the sealer 62 that seals the Hall IC 60). Thereby, the face 82 on second axial end of the cylinder part 85 faces the center section 31 of the second magnetic flux transmission part 30.

In the present embodiment shown in FIGS. 6A-6C, when (i) the area size of the face 71 on an IC 60 side of the first collector 73 and the area size of the face 81 on an IC 60 side of the second collector 83 are respectively designated as A1, and (ii) the area size of the opposite face 72 on the opposite side of the first collector 73 that is not facing the IC 60 and the area size of the opposite face 82 on the opposite side of the second collector 83 are respectively designated as A2, the first magnetic flux collector 73 and the second magnetic flux collector 83 are respectively formed to fulfill a relationship A1<A2. In such manner, similar to the first embodiment, the spill magnetic flux flowing through the gap 101 between the first magnetic flux transmission part 20 and the second magnetic flux transmission part 30 is further concentrated to flow to or pass through the Hall IC 60.

### Third Embodiment

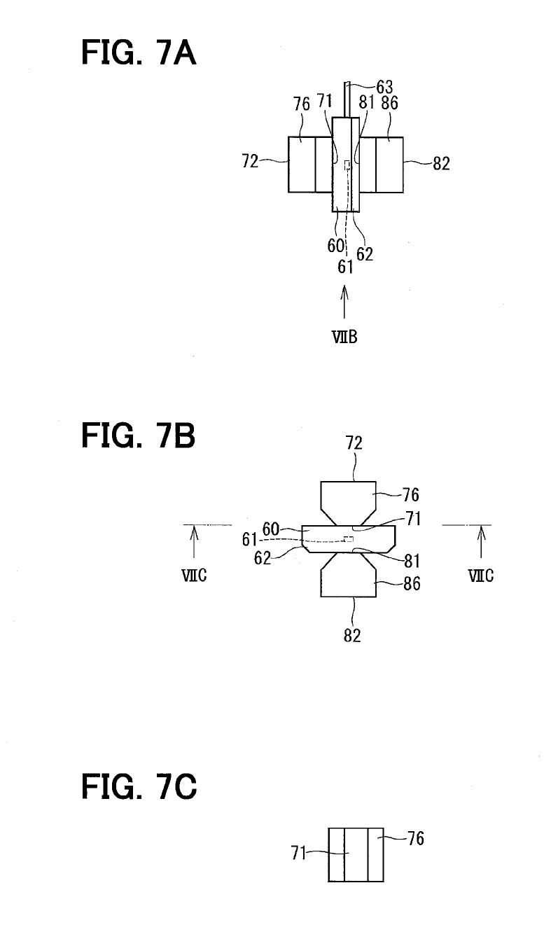

A part of the position detector in the third embodiment of the present disclosure is shown in FIGS. 7A-7C. The position detector in the third embodiment differs from the first embodiment in the shape of the first and second magnetic flux collector.

FIGS. 7A-7C shows the Hall IC, the first magnetic flux collector, and the second magnetic flux collector of the position detector in the third embodiment. According to the third embodiment, a first magnetic flux collector 76 is substantially a hexahedron, having two corners cut out or chamfered, therefrom. A face 71 of the first magnetic flux collector 76, which is positioned between two chamfered corners, abuts a face of the sealer 62 at its center (i.e., the face on the first magnetic flux transmission part 20 side of the sealer 62 that seals the Hall IC 60). Thereby, a face 72 on a side of the first magnetic flux collector 76 opposite to the face 81 faces the center section 21 of the first magnetic flux transmission part 20.

Similar to the first collector 76, a second magnetic flux collector 86 is substantially a hexahedron, having two corners cut out or chamfered, therefrom. A face 81 of the second magnetic flux collector 86, which is positioned between two chamfered corners, abuts a face of the sealer 62 at its center (i.e., the face on the second magnetic flux transmission part 30 side of the sealer 62 that seals the Hall IC 60). Thereby, a face 82 on a side of the second magnetic flux collector 86 opposite to the face 81 faces the center section 31 of the second magnetic flux transmission part 30.

In the present embodiment shown in FIGS. 7A-7C, when (i) the area size of the face 71 on an IC 60 side of the first collector 76 and the area size of the face 81 on an IC 60 side of the second collector 86 are respectively designated as A1, and (ii) the area size of the opposite face 72 on the opposite side of the first collector 76 that is not facing the IC 60 and the area size of the opposite face 82 on the opposite side of the second collector 86 are respectively designated as A2, the first magnetic flux collector 76 and the second magnetic flux collector 86 are respectively formed to fulfill a relationship A1<A2. In such manner, similar to the first embodiment, the spill magnetic flux flowing through the gap 101 between the first magnetic flux transmission part 20 and the second magnetic flux transmission part 30 is further concentrated to flow to or pass through the Hall IC 60.

### Fourth Embodiment

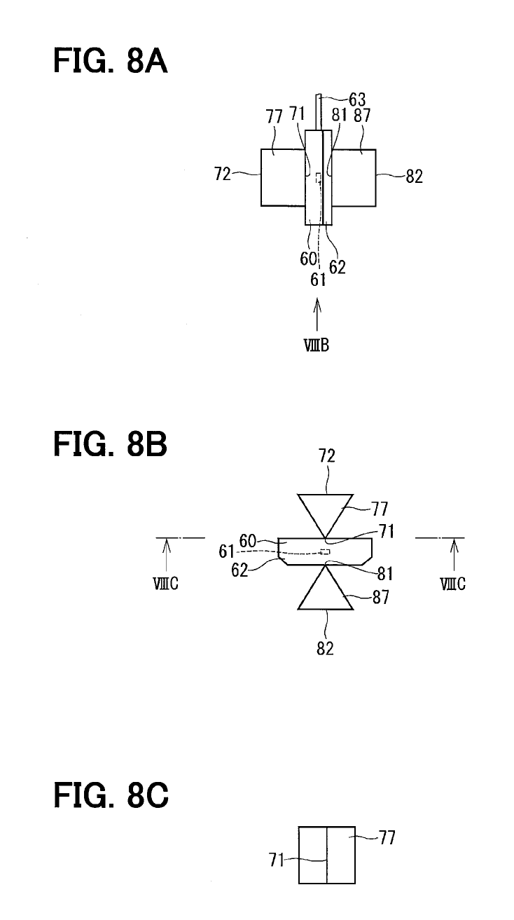

A part of the position detector in the fourth embodiment of the present disclosure is shown in FIGS. 8A-8C. The position detector in the fourth embodiment differs from the first embodiment in the shape of the first and second magnetic flux collector.

FIGS. 8A-8C shows the Hall IC, the first magnetic flux collector, and the second magnetic flux collector of the position detector in the fourth embodiment. According to the fourth embodiment, a first magnetic flux collector 77 has a triangular block shape. The first magnetic flux collector 77 has a face or edge facing or abutting a face of the sealer 62 at its center (i.e., the face on the first magnetic flux transmission part 20 side of the sealer 62 that seals the Hall IC 60), and has a face 72 on a side of the first magnetic flux collector 77 that faces the center section 21 of the first magnetic flux transmission part 20. The face or edge of the collector 77 has a zero-area face 71 formed thereon, which may actually be a “line” with its area size configured to be equal to zero.

A second magnetic flux collector 87 has a triangular block shape, similar to the first collector 77. The second magnetic flux collector 87 has a face or edge facing or abutting a face of the sealer 62 at its center (i.e., the face on the first magnetic flux transmission part 20 side of the sealer 62 that seals the Hall IC 60), and has a face 82 on a side of the second magnetic flux collector 87 that faces the center section 31 of the second magnetic flux transmission part 30. The face or edge of the collector 87 has a zero-area face 81 formed thereon, which may actually be a “line” with its area size configured to be equal to zero.

In the present embodiment shown in FIGS. 8A-8C, when (i) the area size of the face 71 on an IC 60 side of the first collector 77 and the area size of the face 81 on an IC 60 side of the second collector 87 are respectively designated as A1, and (ii) the area size of the opposite face 72 on the opposite side of the first collector 77 that is not facing the IC 60 and the area size of the opposite face 82 on the opposite side of the second collector 87 are respectively designated as A2, the first magnetic flux collector 77 and the second magnetic flux collector 87 are respectively formed to fulfill a relationship A1<A2 and A1=0. In such manner, similar to the first embodiment, the spill magnetic flux flowing through the gap 101 between the first magnetic flux transmission part 20 and the second magnetic flux transmission part 30 is further concentrated to flow to or pass through the Hall IC 60.

Further, in the present embodiment, when the area size of a face on the first collector 77 side of the Hall element 61 or the area size of a face on the second collector 87 side of the Hall element 61 is designated as A0, the Hall element 61, the first magnetic flux collector 77, and the second magnetic flux collector 87 are respectively formed to fulfill a relationship A1<A0 and A1=0.

### Fifth Embodiment

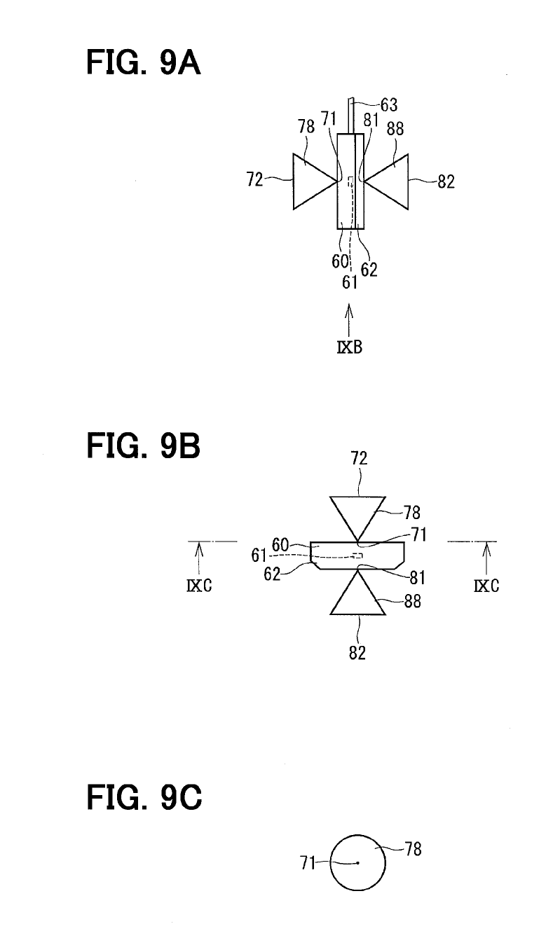

A part of the position detector in the fifth embodiment of the present disclosure is shown in FIGS. 9A-9C. The position detector in the fifth embodiment differs from the first embodiment in the shape of the first and second magnetic flux collector.

FIGS. 9A-9C shows the Hall IC, the first magnetic flux collector, and the second magnetic flux collector of the position detector in the fifth embodiment. According to the fifth embodiment, a first magnetic flux collector 78 has a cone shape. The first magnetic flux collector 78 has an apex facing or abutting a face of the sealer 62 at its center (i.e., the face on the first magnetic flux transmission part 20 side of the sealer 62 that seals the Hall IC 60), and has the face 72 which serves as a bottom of the collector 78 faced to the center section 21 of the first magnetic flux transmission part 20. The apex of the first magnetic flux collector 78 has a zero-area face 71 formed thereon, which may actually be a “point” with its area size configured to be equal to zero.

A second magnetic flux collector 88 has a cone shape, similar to the first collector 78. The second magnetic flux collector 88 has an apex facing or abutting a face of the sealer 62 at its center (i.e., the face on the second magnetic flux transmission part 30 side of the sealer 62 that seals the Hall IC 60), and has the face 82 which serves as a bottom of the collector 88 faced to the center section 31 of the second magnetic flux transmission part 30. The apex of the second magnetic flux collector 88 has a zero-area face 81 formed thereon, which may actually be a “point” with its area size configured to be equal to zero.

In the present embodiment shown in FIGS. 9A-9C, when (i) the area size of the face 71 on an IC 60 side of the first collector 78 and the area size of the face 81 on an IC 60 side of the second collector 88 are respectively designated as A1, and (ii) the area size of the opposite face 72 on the opposite side of the first collector 78 that is not facing the IC 60 and the area size of the opposite face 82 on the opposite side of the second collector 88 are respectively designated as A2, the first magnetic flux collector 78 and the second magnetic flux collector 88 are respectively formed to fulfill a relationship A1<A2 and A1=0. In such manner, similar to the first embodiment, the spill magnetic flux flowing through the gap 101 between the first magnetic flux transmission part 20 and the second magnetic flux transmission part 30 is further concentrated to flow to or pass through the Hall IC 60.

Further, in the present embodiment, when the area size of a face on the first collector 78 side of the Hall element 61 or the area size of a face on the second collector 88 side of the Hall element 61 is designated as A0, the Hall element 61, the first magnetic flux collector 78, and the second magnetic flux collector 88 are respectively formed to fulfill a relationship A1<A0 and A1=0.

### Sixth Embodiment

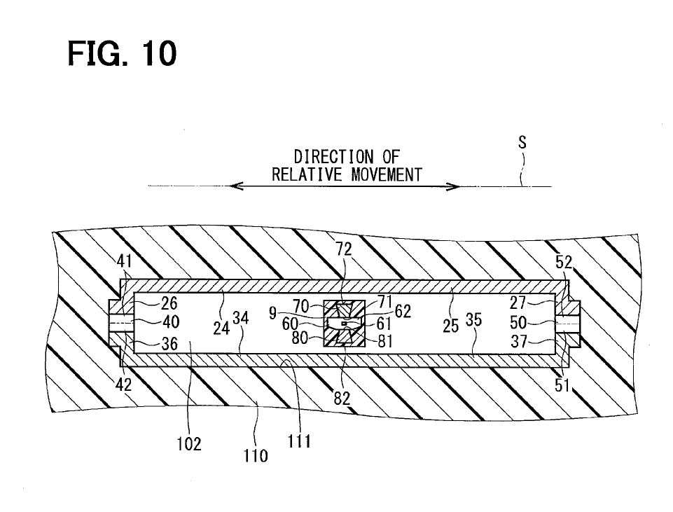

The position detector in the sixth embodiment of the present disclosure is shown in FIG. 10. The sixth embodiment differs from the first embodiment in the shape of the first and second magnetic flux transmission part and in the other part.

According to the sixth embodiment, a mover 110 serving as a detection object is attached to a manual valve which switches a shift of a gearbox of a vehicle, for example. The manual valve moves linearly in an axial direction, for switching the shift of the gearbox. The mold 9 is fixed onto a separate member that is close to but separate from the manual valve. That is, the mover 110 moves linearly relative to the mold 9 that serves as a reference part.

According to the present embodiment, the position detector detects the position of the mover 110 that moves linearly relative to the mold 9. Thereby, the position of the manual valve is detected and an actual shift position of the gearbox is detected. Thus, the position detector can be used as a stroke sensor (i.e., a linear movement sensor).

As shown in FIG. 10, in the present embodiment, a first magnetic flux transmission part 24 is disposed in a cavity having a rectangular shape bored in the mover 110. The first magnetic flux transmission part 24 has a center section 25, a first end 26, and an second end 27. The center section 25 has a straight shape which is in parallel with a virtual straight line S extending in a direction of the relative movement of the mover 110. The first end 26 extends substantially perpendicularly from one end of the center section 25 relative to the virtual straight line S. The second end 27 extends from the other end of the center section 25 in the same direction as the first end 26.

A second magnetic flux transmission part 34 is also disposed in the cavity 111 of the mover 110. The second magnetic flux transmission part 34 has a center section 35, a first end 36, and an second end 37. The center section 35 has a straight shape which is in parallel with the virtual straight line S similar to the center section 25. The first end 36 extends substantially perpendicularly from one end of the center section 35 relative to the virtual straight line S, to face the first end 26. The second end 37 extends from the other end of the center section 35 in the same direction as the first end 36.

As shown in FIG. 10, the first magnetic flux transmission part 24 and the second magnetic flux transmission part 34 are formed in the cavity 111 of the mover 110 so that the center section 25 and the center section 35 face each other in a direction that is perpendicular to the virtual straight line S. Thereby, a rectangular shape gap 102 is defined between the center section 25 of the first magnetic flux transmission part 24 and the center section 35 of the second magnetic flux transmission part 34.

The configuration of the sixth embodiment is similar to that of the first embodiment, other than the above-described points.

According to the present embodiment, the magnetic flux density detected by the Hall IC 60 is illustrated by a line L1 in FIG. 4, if “a rotation position (θ)” of FIG. 4 is read as a “position” in a path of relative movement of the mover 110.

In the present embodiment, since the first magnetic flux collector 70 and the second magnetic flux collector 80 are formed to fulfill a relationship A1<A2, the collectors 70, 80 are enabled to concentrate the spill magnetic flux flowing through the gap 101 between the first magnetic flux transmission part 20 and the second magnetic flux transmission part 30, and to flow the magnetic flux to (i.e., to pass the flux through) the Hall IC 60 in a further concentrated manner.

### Other Embodiments

According to other embodiments of the present disclosure, as long as a magnetic flux collector fulfills the relationship A1<A2, the collector may have any shape. Further, the signal output element and the magnetic flux collector may also be formed to fulfill the relationship A0=A1.

In the above-mentioned embodiments, the examples are described for showing that the first magnetic flux transmission part, the second magnetic flux transmission part, the first magnetic flux generator, and the second magnetic flux generator may be disposed on the detection object, and the magnetic flux density detector may be disposed on the reference part.

On the other hand, in other embodiments of the present disclosure, the first magnetic flux transmission part, the second magnetic flux transmission part, the first magnetic flux generator, and the second magnetic flux generator may be disposed on the reference part, and the magnetic flux density detector may be disposed on the detection object.

In other embodiments of the present disclosure, the polarity of the magnet disposed at a position between the both ends of the first magnetic flux transmission part and the second magnetic flux transmission part may be flipped or reversed from the orientation in the above-described embodiments.

Further, in other embodiments of the present disclosure, the motor may have a speed reducer for reducing the number of rotations to be transmitted to the output shaft.

Additionally, in other embodiments of the present disclosure, each of the above-mentioned embodiments may be combined with other embodiments.

Moreover, in other embodiments of the present disclosure, an actuator may be used, for example, as a driving power source of various devices, such as a wastegate valve operation device, a variable vane control device of a variable capacity turbocharger, a valve operation device of an exhaust throttle or an exhaust switch valve, a valve operation device of a variable air intake mechanism, and the like.

Although the present disclosure has been fully described in connection with the above embodiment thereof with reference to the accompanying drawings, it is to be noted that various changes and modifications will become apparent to those skilled in the art, and such changes and modifications are to be understood as being within the scope of the present disclosure as defined by the appended claims.

What is claimed is:

1. A position detector detecting a position of a detection object that moves relative to a reference part, the position detector comprising:
a first magnetic flux transmission part disposed on one of the detection object or the reference part, the first magnetic flux transmission part having a first end and a second end;
a second magnetic flux transmission part facing the first magnetic flux transmission part in a facing direction and disposed to define a gap between the first magnetic flux transmission part and the second magnetic flux transmission part, the second magnetic flux transmission part having a first end and a second end;
a first magnetic flux generator disposed at a position between the first end of the first magnetic flux transmission part and the first end of the second magnetic flux transmission part;
a second magnetic flux generator disposed at a position between the second end of the first magnetic flux transmission part and the second end of the second magnetic flux transmission part;
a magnetic flux density detector (i) disposed on an other of the detection object or the reference part to be movable within the gap relative to the one of the detection object or the reference part and (ii) having a signal output element that outputs a signal according to a density of a magnetic flux passing through the magnetic flux density detector; and
a magnetic flux collector having two facing parts contacting opposite sides of the magnetic flux density detector with each of the two facing parts having a first side that faces the magnetic flux density detector and a second side that is a side opposite to the first side, and the two facing parts being aligned in a direction that matches the facing direction of the first magnetic flux transmission part and the second magnetic flux transmission part, wherein
the first side has an area size defined as A1,
the second side has an has an area size defined as A2, and
the magnetic flux collector is configured to fulfill an area size relationship of A1<A2.

2. The position detector of claim 1, wherein
the signal output element has faces adjacent to each of the two facing parts of the magnetic flux collector,
at least one of the faces adjacent to each of the two facing parts has an area size defined as A0, and
the signal output element and the magnetic flux collector are configured to fulfill a relationship of A0≦A1.

3. The position detector of claim 1, wherein
the detection object rotates relative to the reference part, and
the first magnetic flux transmission part and the second magnetic flux transmission part have a curved shape that is concentric to a center of rotation of the detection object.

4. The position detector of claim 1, wherein
the detection object moves linearly relative to the reference part, and
the first magnetic flux transmission part and the second magnetic flux transmission part have a straight shape that extends along a path of relative movement of the detection object.
